(19) United States
(12) Patent Application Publication
(10) Pub. No.: US 2001/0040296 A1
(43) Pub. Date: Nov. 15, 2001

(54) Printed-circuit board and method of mounting electric components thereon

(76) Inventor: Katsuaki Hiromatsu, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/728,333

(22) Filed: Dec. 1, 2000

(30) Foreign Application Priority Data
Dec. 28, 1999 (JP) 11-373935

(51) Int. Cl. H01L 23/48; H01L 23/52; H01L 29/40; H01L 21/44; H01L 21/48; H01L 21/50

(52) U.S. Cl. 257/774; 257/779; 438/125; 438/612

(57) ABSTRACT

It is an object of the invention to provide a low cost printed-circuit board capable of achieving high density of mounting of the surface mounting components and of designing of conductive patterns while keeping speeding up a transmission speed of a signal pattern and reducing a noise, and a method of mounting electric components on the printed-circuit board. Component mounting pads formed of conductive patterns are disposed on a surface of the printed-circuit board at two locations thereof, and through holes for connecting printed-circuit boards of a multi-layer printed-circuit board are defined in the component mounting pads. The through holes are filled up by a resist ink from the electric component non-mounting surface when the printed-circuit board is manufactured. As a result, a sealed air-layer is formed inside the through holes when a solder is pasted or soldered onto the printed-circuit board.

### BACKGROUND OF THE INVENTION

1. Field of the Invention

The invention relates to a printed-circuit board having through holes for connecting each printed-circuit board of a multi-layer printed-circuit board and pads on which varieties of electric components such as an integrated circuit (IC) are mounted, and a method of mounting the electric components on the printed-circuit board.

2. Related Art

An apparatus for machining and manufacturing a multi-layer printed-circuit board is developed wherein varieties of electronic components such as an IC constituting electronic equipment, e.g., a page testing device (pager) are mounted on the surface of the multi-layer printed-circuit board. The multi-layer printed-circuit board is manufactured by providing through holes for connecting between a plurality of double sided printed-circuit boards and aligning the plurality of printed-circuit boards with one another, applying a milling machining to the lower layer printed-circuit board, holding an insulating layer while the lower layer printed-circuit board is positioned downward to press the multi-layer printed-circuit board by a press machine. After conductive patterns are formed on the surface of the printed-circuit board, an external shaping machining is subsequently applied to the printed-circuit board.

FIG. 2(A) is a plan view showing a disposition of each pad 12 on which an electric component 15 is mounted (hereinafter referred to as electric component mounting pad 12) and each through hole 13 is disposed on the surface of a conventional printed-circuit board 11. As shown in FIG. 2(A), when an electric component such as an IC is mounted on the surface of the conventional printed-circuit board 11, it is necessary to dispose the electric component mounting pads 12 on the conventional printed-circuit board 11. In the case where the electric component mounting surface is other than the surface of the printed-circuit board 11 or the electric components are electrically connected to each other by way of an electric field layer, the printed-circuit board 11 is perforated to form the through holes 13, through which the electric components are electrically connected to the printed-circuit board 11.

However, the mounting construction of the conventional printed-circuit board 11 as shown in FIG. 2(A) has the following problems. Since both the electric component mounting pads 12 and through holes 13 occupy a fixed area on the printed-circuit board 11, resulting in producing factors in the impediment of disposition of an electric component such as an IC and design of conductive patterns, and so forth. Further, these factors cause the reduction of speed of an electric signal and the production of a noise on the printed-circuit board 11 on which the electric components are mounted because these factors have an electric capacitance as an electric property on the electric circuit.

Further, as shown in FIG. 2(B), when the electric component 15 to be mounted on the surface of the printed-circuit board (hereinafter referred to as a surface mounting component 15) is soldered onto the printed-circuit board 11, a solder 16 flows inside the through hole 13, so that there occurs the shortage of the solder at the portion where the surface mounting component 15 and printed-circuit board 11 are connected to each other and insufficient connection between the surface mounting component 15 and printed-circuit board 11.

There are following techniques for solving the foregoing problems. For example, as one technique, a mask 18 formed of resist ink is provided between the through hole 13 and surface mounting component 15 as shown in FIG. 3 to prevent the solder 16 from reaching the through hole 13 in advance. As another technique, the inside of the through hole 13 is filled with a resin or the like to prevent the solder 16 from entering the through hole 13. However, these techniques cost high, and they are not put to a practical use.

### SUMMARY OF THE INVENTION

It is an object of the invention to provide a low-priced printed-circuit board capable of keeping high density of mounting of the electric components and of designing of conductive patterns, thereby speeding up a transmission speed of a signal pattern, reducing a noise, and a method of mounting electric components on the printed-circuit board.

To achieve the above object, the printed-circuit board according to a first aspect of the invention comprises electric component mounting pads each having a through hole therein for connecting between printed-circuit boards of a multi-layer printed-circuit board wherein the electric components are mounted on each electric mounting pad (e.g., corresponding to a printed-circuit board 1 as shown in FIG. 1) by way of a solder, characterized in that each through hole (e.g., corresponding to a through hole 3 as shown in FIG. 1) is filled up and blocked by a filling-up material (e.g., corresponding to resist ink 4 as shown in FIG. 1) from the back side thereof, namely, the side where the electric component is not mounted (hereinafter referred to as electric component non-mounting surface).

The method of mounting electric components on a printed-circuit board according to a fourth aspect of the invention comprises the steps of forming through holes for connecting between printed-circuit boards of a multi-layer printed-circuit board on the surface of electric component mounting pads, mounting the electric components on the surface of the printed-circuit board by way of a solder, characterized in further comprising the step of filling up the through holes with a filling-up material from an electric component non-mounting surface.

According to the first or fourth aspects of the invention, the through holes are blocked by the filling-up material from the electric component non-mounting surface.

Accordingly, it is possible to provide a low-priced printed-circuit board for holding down a cost of electric components and capable of achieving high density of mounting of the electric components and of designing of conductive patterns while keeping speeding up a transmission speed of a signal pattern and reducing a noise. Further, strengths of electric component mounting pads and the through holes are increased, improving a reliability of the printed-circuit board.

The printed-circuit board according to the second aspect of the invention is characterized in that the filling-up material (e.g. corresponding to an resist ink 4 in FIG. 1) according to the printed-circuit board of the first aspect of the invention forms an air layer inside the through holes for preventing the solder from entering the interior of the through holes.

The method of mounting electric components on a printed-circuit board according to the fifth aspect of the invention is characterized in that in the step of filling up the through holes according to the fourth aspect of the invention an air layer is formed inside the through holes for preventing the solder from entering the interior of the through holes.

According to the second or fifth aspect of the invention, the filling-up material forms an air layer inside the through holes for preventing the solder from entering the interior of the through holes.

Accordingly, these aspects of the invention has an effect, in addition to the effect obtained by the first or fourth aspect of the invention, of preventing the shortage of a solder on the bonding surface caused by the flow of the solder into the through holes when the electric components are soldered onto the printed-circuit board.

The printed-circuit board according to the third aspect of the invention is characterized in that the filling-up material according to the second aspect of the invention is formed of resist ink (e.g. corresponding to a resist ink 4 in FIG. 1).

Accordingly, the third aspect of the invention has an effect, in addition to the effect of the second aspect of the invention, of easily forming the shape of the filling-up material for filling up the through holes.

### BRIEF DESCRIPTION OF THE DRAWINGS

FIG. 1(A) to FIG. 1(C) show the construction of a printed-circuit board according to the preferred embodiment of the invention wherein

FIG. 1(A) is a plan view showing a disposition of an electric component on the printed-circuit board,

FIG. 1(B) is a plan view showing that the through holes are filled up with a resist ink, and

FIG. 1(C) is a sectional view showing that the through hole is filled up with the resist ink;

FIG. 2(A) and FIG. 2(B) show the construction of the conventional printed-circuit board wherein

FIG. 2(A) is a plan view showing a disposition of an electric component on the printed-circuit board, and

FIG. 2(B) is a sectional view showing that a masking is not applied to a component mounting pad by resist ink; and

FIG. 3 is a sectional view showing that a masking is applied to the component mounting pad on the conventional printed-circuit board.

### PREFERRED EMBODIMENT OF THE INVENTION

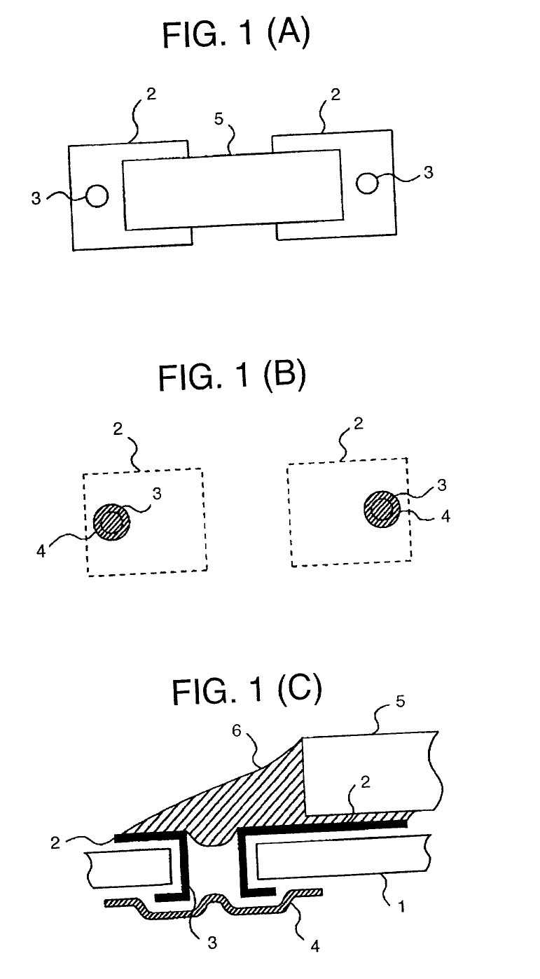

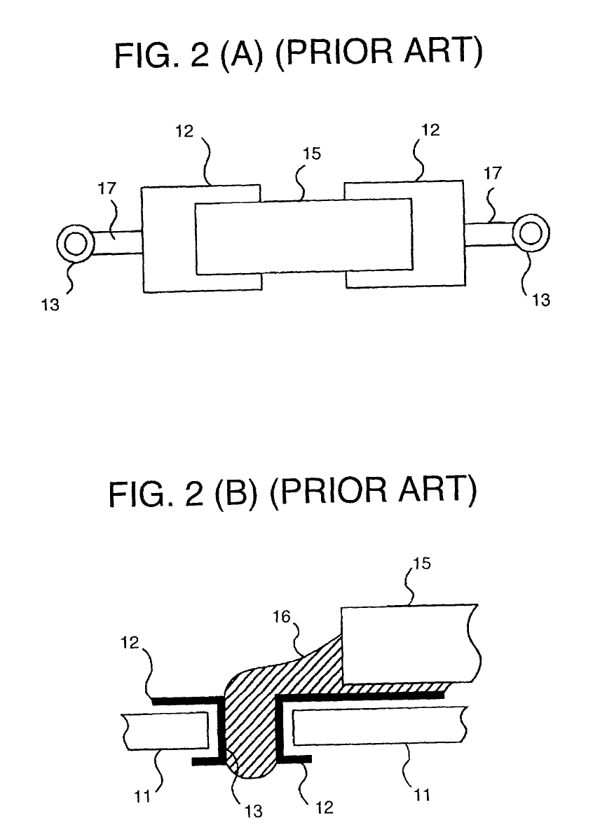

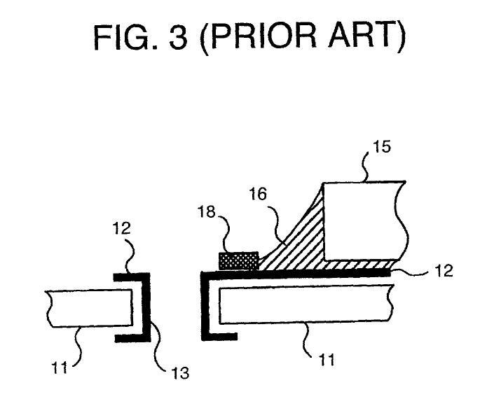

The construction of mounting electric components on a printed-circuit board 1 according to a preferred embodiment of the invention is now described with reference to FIGS. 1(A) to (C). As shown in FIG. 1(A), component mounting pads 2 each formed of a conductive pattern is disposed on a surface of the printed-circuit board 1 at two locations, and through holes 3 for connecting the printed-circuit boards 1 of a multi-layer printed-circuit board are defined in the component mounting pads 2. At this time, the component mounting pads 2 serve as lands for reinforcing the through holes 3. Subsequently, as shown in FIG. 1(B), the through holes 3 are filled up by a resist ink 4 from the side opposite to the surface on which the electric components are mounted when manufacturing the printed-circuit board. FIG. 1(C) is a partially sectional view showing that a surface mounting component 5 is mounted on the printed-circuit board 1 in FIG. 1(B). As shown in FIG. 1(C), when the through holes 3 are filled up by the resist ink 4 from an electric component non-mounting surface, a sealed air-layer is formed inside the through holes 3 when a solder 6 is pasted or soldered onto between the surface mounting component 5 and the printed-circuit board 1.

As a result, it is possible to define the through holes 3 in the electric component mounting part 2 while preventing the shortage of a solder on the bonding surface caused by the flow of the solder into the through holes when the electric components are soldered onto the printed-circuit board. Accordingly, it is possible to achieve high density of mounting of the surface mounting component 5 and of designing of conductive patterns and also possible to achieve the speeding up a transmission speed of a signal pattern and reducing a noise. Further, strengths of electric component mounting pads and the through holes are increased, improving a reliability of the printed-circuit board compared with a case where the through holes 3 are independently provided of the electric component mounting pads 2.

The invention is not limited to the foregoing preferred embodiment but it can be appropriately changed without departing from the scope of the spirit of the invention.

For example, although the resist ink 4 is employed as the filling-up material of the through holes 3, the filling-up material may be any form such as solvent resistant or heat resistant ink capable of solving the foregoing problems.

The invention has the following effects.

According to the first aspect of the invention, since the through hole is blocked up by the filling-up material from the electric component non-mounting surface, it is possible to provide a low cost printed-circuit board for holding down electric components capable of achieving high density of mounting of the surface mounting component and of designing of conductive patterns while keeping speeding up a transmission speed of a signal pattern and reducing a noise.

According to the second aspect of the invention, in addition to the effect of the first aspect of the invention, it is possible to prevent the shortage of a solder on the bonding surface caused by the flow of the solder into the through holes when the electric components are soldered onto the printed-circuit board when the surface mounting component is mounted on the printed-circuit board.

According to the third aspect of the invention, in addition to the effect the second aspect of the invention, the shape of the filling-up material for filling up the through holes can be easily formed.

According to the fourth aspect of the invention, it is possible to proved a method of mounting electric components on a printed-circuit board for holding down electric components capable of achieving high density of mounting of the surface mounting component and of designing of conductive patterns while keeping speeding up a transmission speed of a signal pattern and reducing a noise.

According to the fifth aspect of the invention, in addition to the effect the fourth aspect of the invention, it is possible to provide a method of mounting electric components on a printed-circuit board capable of preventing the shortage of a solder on the bonding surface caused by the flow of the solder into the through holes when the electric components are soldered onto the printed-circuit board.

What is claimed is:

1. A printed-circuit board comprising electric component mounting pads each having a through hole for connecting between printed-circuit boards of a multi-layer printed-circuit board wherein the electric components are mounted on the electric component mounting pads by way of a solder, wherein the through holes are filled up and blocked by a filling-up material from the side where the electric components are not mounted.

2. The printed-circuit board according to claim 1, wherein the filling-up material forms an air layer inside the through holes for preventing the solder from entering the interior of the through holes.

3. The printed-circuit board according to claim 2, wherein the filling-up material is formed of resist ink.

4. A method of mounting electric components on a printed-circuit board comprising the steps of:
forming through holes for connecting between printed-circuit boards of a multi-layer printed-circuit board on the surface of electric component mounting pads;
mounting the electric components on the surface of the electric component mounting pads by way of a solder; and
filling up the through holes with a filling-up material from the side where electrical components are not mounted.

5. The method of mounting electric components on a printed-circuit board according to claim 4, wherein in the step of filling up the through hole with the filling-up material an air layer is formed inside the through holes for preventing the solder from entering the interior of the through holes.
